(19) United States
(12) Patent Application Publication
(10) Pub. No.: US 2015/0307995 A1
(43) Pub. Date: Oct. 29, 2015

(54) ELECTROLESS DEPOSITION OF CONTINUOUS PALLADIUM LAYER USING COMPLEXED Co2+ METAL IONS OR Ti3+ METAL IONS AS REDUCING AGENTS

(71) Applicant: Lam Research Corporation, Fremont, CA (US)

(72) Inventors: Eugenijus NORKUS, Vilnius (LT); Aldona JAGMINIENE, Vilnius (LT); Ina STANKEVICIENE, Vilnius (LT); Aniruddha JOI, Fremont, CA (US); Yezdi DORDI, Palo Alto, CA (US)

(73) Assignee: Lam Research Corporation, Fremont, CA (US)

(21) Appl. No.: 14/265,001

(22) Filed: Apr. 29, 2014

(51) Int. Cl. C23C 18/52; H01L 21/288

(52) U.S. Cl. CPC C23C 18/52; H01L 21/288

(57) ABSTRACT

A solution for electroless deposition of palladium is provided. A reducing agent of Co²⁺ or Ti³⁺ ions is provided to the solution. Pd²⁺ ions are provided to the solution.

### BACKGROUND OF THE INVENTION

### Field of the Invention

The invention relates to a method of forming semiconductor devices on a semiconductor wafer. More specifically, the invention relates to depositing palladium layers to form semiconductor devices.

In forming semiconductor devices, thin layers of palladium may be deposited. Such a deposition may be provided by electroless plating.

### SUMMARY OF THE INVENTION

To achieve the foregoing and in accordance with the purpose of the present invention, a solution for electroless deposition of palladium is provided. A reducing agent of Co²⁺ or Ti³⁺ ions is provided to the solution. Pd²⁺ ions are provided to the solution.

In another manifestation of the invention, a method for providing an electroless plating of a palladium containing layer is provided. A Ti³⁺ or Co²⁺ concentrated stock solution is provided. A Pd²⁺ concentrated stock solution is provided. A flow from the Ti³⁺ or Co²⁺ concentrated stock solution is combined with a flow from the Pd²⁺ concentrated stock solution and water to provide a mixed electrolyte for electrolessly depositing Pd. A substrate is exposed to the mixed electrolyte for electrolessly depositing Pd.

In another manifestation of the invention, a method for providing an electroless plating of a palladium layer is provided. A solution for electroless deposition of palladium is provided, comprising Ti³⁺ or Co²⁺ ions and Pd²⁺ ions, wherein a ratio of Ti³⁺ or Co²⁺ ions to Pd²⁺ ion is between 100:1 to 2:1. A substrate is exposed to the solution for electroless deposition of palladium.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a flow chart of an embodiment of the invention.

FIG. 2 is a schematic view of a system that may be used in an embodiment of the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In electroless deposition (ELD) on difficult to plate substrates, activation of the substrate using Pd containing solutions prior to deposition is important. This may be accomplished by simply dipping the solution in a PdCl₂ aqueous solution. Pd²⁺ ions adsorb on the substrate creating an active surface which may or may not have a uniform Pd surface coverage after reduction. This gives rise to non-homogeneous nucleation which is undesirable in semiconductor applications. Hence, ability to deposit a thin, continuous Pd layer on substrates, prior to plating, is important. Pd can be deposited by ELD. Electroless deposition of palladium is accomplished using hydrazine or other hydrogen containing compounds as reducing agents. In addition to the environmental concerns associated with these hydrogen containing reducing agents, the oxidation reaction of these species involves generation of H₂ gas which is incorporated in the deposit. This impacts the purity of the deposited film. Additionally, the hydrazine-palladium electrolyte requires operation at an elevated temperature and high pH. These are undesirable for application in back end metallization as the dielectric materials are prone to damage at high pH and temperature.

In electroless plating bath containing Co²⁺ or Ti³⁺, the metal to be deposited, Pd²⁺, is reduced from the solution while Ti³⁺ or Co²⁺ are oxidized to higher, more stable oxidation states. Co²⁺ or Ti³⁺ have significant benefits over hydrazine and other hydrogen containing compounds in resolving the issues specified earlier.

Replacing hydrazine with metal ion reducing agents eliminates the toxicity and volatility that is inherent to hydrazine and makes the plating bath more environmentally friendly. Additionally, no gas evolution (i.e. H₂ and N₂) or side reaction is observed at the electrode. This results in a smooth, continuous, pure Pd film. The metal ion containing plating baths can also be operated over a wide temperature and pH range.

The inventive metal ion reducing agents containing bath is operable at room temperature and lower pH. This is not possible with the hydrazine and other reducing agent containing electrolyte. The extended window of operation makes this bath attractive for application in semiconductor applications In addition, this embodiment allows the formation of a very thin, continuous Pd film on substrates that can be used as a catalyst layer for subsequent ELD of different metals such as Cu, Ni, Co etc. In addition, this embodiment provides an environmentally friendly and ‘greener’ alternative to hydrazine based electroless Pd electrolytes which are highly toxic and unstable.

Gas evolution (mainly hydrogen and/or nitrogen) which is a byproduct of the hydrazine oxidation reaction is eliminated by the cobalt and titanium oxidation reactions. Deposition of a pure, continuous Pd film is possible.

The cost and complexity associated with maintaining a high temperature during plating can also be reduced due to near room temperature operation of the metal ion reducing agents electrolyte.

The table below describes a formulation of the Ti³⁺/Pd electroless plating bath. The deposition was done on Cu substrates without any activation. Deposition can be extended to non conductive or poorly conducting substrates such as glass, and 1˜2 nm Ru by following proper pre-clean protocols.

| Species | Concentration (M) |
|---|---|
| PdCl₂ | 0.004 |
| Sodium Tartrate | 0.15 |
| Sodium Gluconate | 0.025 |
| NH₄OH | 0.32 |
| TiCl₃ | 0.05 |
| Temperature | 20° C. |
| pH | 2-7 |

The Ti³⁺ or Co²⁺ metal ion reducing agents containing bath, used in an embodiment of the invention, is operable below room temperature and with a low pH. This is not possible with the hydrazine and other reducing agent containing electrolyte.

Formation of Pd electrodes for memory applications using plasma etching is difficult. An embodiment of the invention enables selective patterning of Pd electrodes in semiconductor manufacturing without using plasma etching. The cost and complexity associated with maintaining a high temperature during plating can also be reduced due to near room temperature operation of the Ti³⁺ or Co²⁺ metal ion reducing agent electrolytes.

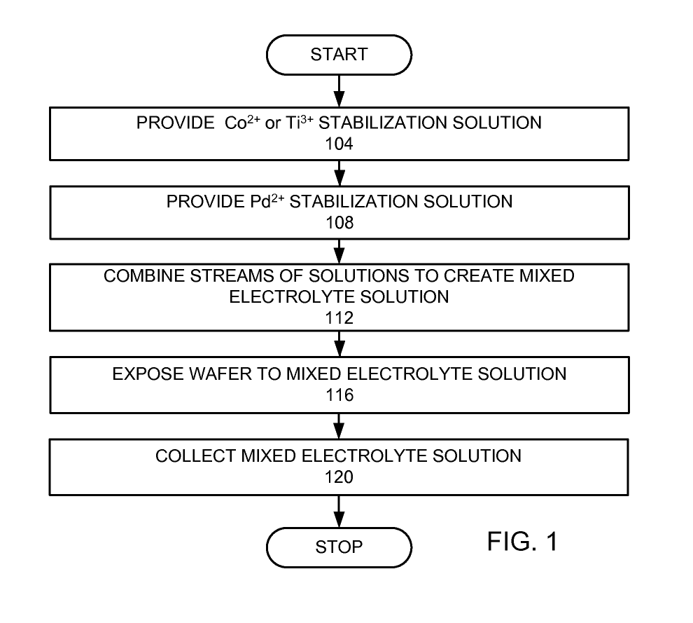

FIG. 1 is a high level flow chart of an embodiment of the invention. In this embodiment, a Ti³⁺ or Co²⁺ concentrated stock solution is provided (step 104). A Pd²⁺ concentrated stock solution is provided (step 108). A flow from the Ti³⁺ or Co²⁺ concentrated stock solution is combined with a flow from the Pd²⁺ concentrated stock solution and water to provide a mixed electrolyte solution of the Ti³⁺ or Co²⁺ concentrated stock solution and the Pd²⁺ concentrated stock solution (step 112). A wafer is exposed to the mixed electrolyte solution of the Ti³⁺ or Co²⁺ concentrated stock solution and the Pd²⁺ concentrated stock solution (step 116). The mixed electrolyte solution is collected and may be reactivated for future use or disposed (step 120).

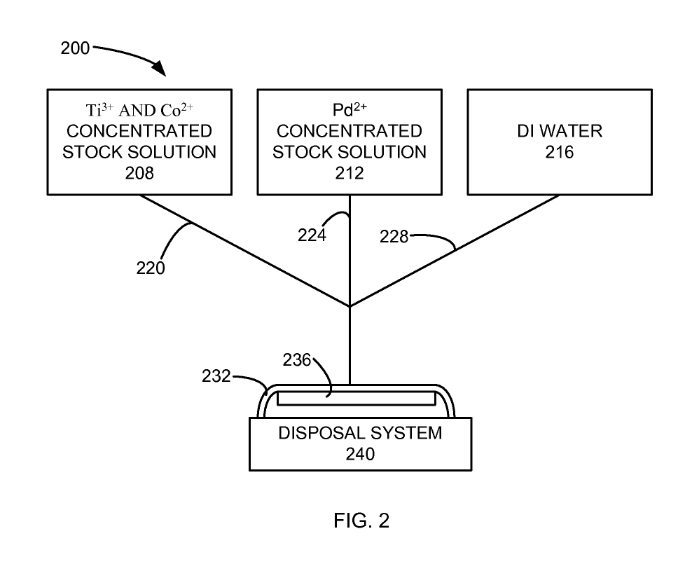

In an example, a Ti³⁺ or Co²⁺ concentrated stock solution is provided in a Ti³⁺ or Co²⁺ concentrated stock solution source (step 104). A Pd²⁺ concentrated stock solution is provided in a Pd²⁺ concentrated stock solution source (step 108). FIG. 2 is a schematic view of a system 200 that may be used in an embodiment of the invention. The system comprises a Ti³⁺ or Co²⁺ concentrated stock solution source 208 containing a Ti³⁺ or Co²⁺ concentrated stock solution, a Pd²⁺ concentrated stock solution source 212 containing a Pd²⁺ concentrated stock solution, and a deionized water (DI) source 216 containing DI. A flow 220 from the Ti³⁺ or Co²⁺ concentrated stock solution source 208 is combined with a flow 224 from the Pd²⁺ concentrated stock solution source 212 and a flow 228 from the DI water source 216 to provide a mixed electrolyte solution 232 of the Ti³⁺ or Co²⁺ concentrated stock solution and the Pd²⁺ concentrated stock solution (step 112). A wafer 236 is exposed to the mixed electrolyte solution 232 of the Ti³⁺ or Co²⁺ concentrated stock solution and the Pd²⁺ concentrated stock solution (step 116). The mixed electrolyte solution 232 is collected (step 120). A disposal system 240 may be used to dispose the mixed electrolyte solution 232. An alternative embodiment provides the collection of the mixed electrolyte solution 232, which is reactivated.

In this example, the Ti³⁺ or Co²⁺ concentrated stock solution comprises a TiCl₃ solution. The Pd²⁺ concentrated stock solution comprises PdCl₂, sodium gluconate, and ammonium hydroxide.

In one embodiment, the flow 220 of the Ti³⁺ or Co²⁺ concentrated stock solution is combined with the flow 224 of the Pd²⁺ concentrated stock solution and the flow 228 of DI water, to form a mixed electrolyte solution of 0.05M TiCl₃, 0.32M NH₄OH, 0.004M PdCl₂, 0.15M Sodium Tartrate, and 0.025M Sodium Gluconate. The mixed electrolyte solution has a pH of between 2-7 and a temperature of about 20° C.

The Ti³⁺ or Co²⁺ concentrated stock solution provides a stable Ti³⁺ or Co²⁺ solution that has a shelf life of several months without degrading. The high concentration allows the Ti³⁺ or Co²⁺ concentrated stock solution to be stored in a smaller volume. In addition, the Pd²⁺ concentrated stock solution provides a stable Pd²⁺ solution that has a shelf life of several months without degrading. The high concentration allows the Pd²⁺ concentrated stock solution to be stored in a smaller volume. The solutions are combined and diluted just prior to exposing the wafer to the mixed electrolyte solution, since the mixed electrolyte solution does not have as long a shelf life as the concentrated stock solutions.

This embodiment of the invention provides a palladium containing layer with a thickness of between 1 nm and 30 nm. Preferably, the palladium containing layer is pure palladium. Because the palladium containing layer is relatively thin, a dilute bath is sufficient. In one embodiment, the wafer is exposed to a continuous flow of the mixed electrolyte solution. In another embodiment, the wafer is placed in a still bath of the mixed electrolyte solution for a period of time. Since the concentration of palladium and titanium is very low in the mixed electrolyte solution, in one embodiment, the mixed electrolyte solution may be disposed (step 120) after being exposed to the wafer, since the low concentration means that only a small amount of palladium and titanium is discarded. In another embodiment, the mixed electrolyte solution is recycled after being exposed to the wafer. The recycling may be accomplished through reactivation of the mixed electrolyte solution.

Generally the solution mixture used for plating has Ti³⁺ or Co²⁺ and Pd²⁺ ions at a Ti³⁺ or Co²⁺ to Pd²⁺ ion ratio between 100:1 and 2:1. More preferably, the solution mixture used for plating has Ti³⁺ or Co²⁺ and Pd²⁺ ions at a Ti³⁺ or Co²⁺ to Pd²⁺ ion ratio between 50:1 and 3:1. Preferably, the solution mixture has a ratio of amine ligands to Ti³⁺ or Co²⁺ is between 12:1 and 3:1. In addition, the solution mixture has Gluconate from Sodium Gluconate or Gluconic acid. In addition, the Pd²⁺ ions come from PdCl₂. The NH₄⁺ ions, which provide the amine ligands, come from NH₄OH. Without being limited by theory, it is believed that amine ligands help to provide a lower temperature and lower pH palladium deposition.

Generally, a wafer or other plating surface is exposed to the solution mixture at a temperature between 10° to 40° C. A plating surface is a surface on which the palladium containing layer is selectively deposited. Such selective deposition may use a mask to protect surfaces where deposition is not desired. Preferably, the solution mixture has a pH from 2 to 7. Preferably, the solution mixture provides Ti³⁺ or Co²⁺ with a concentration between 0.001-0.500 M. More preferably, the solution mixture provides Ti³⁺ or Co²⁺ with a concentration between 0.010 to 0.100 M. Most preferably, the solution mixture provides Ti³⁺ or Co²⁺ with a concentration between 0.020-0.060 M. The lower temperature and lower pH provide a deposition with less damage to layers provided by the semiconductor fabrication process. In addition, such a process does not require any activation step that might attack and damage the copper substrate. In addition, such a process does not create a gas byproduct.

Preferably, the solution mixture is boron free. Preferably, the solution mixture is phosphorus free. Preferably, the solution mixture is hydrazine free. Preferably, the solution mixture is formaldehyde free. It has been found that providing a solution mixture that is boron, phosphorus, hydrazine, and formaldehyde free allows for a more pure plating that does not have impurities provided by using boron-containing reducing agents, phosphorus-containing reducing agents, hydrazine, or formaldehyde. In addition, avoiding using hydrazine or formaldehyde provides a safer and more environmentally friendlier process.

In other embodiments, the source of Ti³⁺ is Ti₂(SO₄)₃ or other soluble salts of Ti³⁺. In other embodiments, the source of Co²⁺ is cobalt chloride or other soluble salts of Co²⁺. Tartaric acid can be displaced by sodium salts of the isomers of sodium citrate or citric acid. sodium gluconate or gluconic acid can be replaced with methoxyacetic acid or other carboxylic acid ligands.

In one embodiment, the deposited palladium containing layer is at least 99.9% pure palladium. More preferably, the deposited palladium containing layer is pure palladium.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A solution for electroless deposition of palladium, comprising:
a reducing agent of Co²⁺ or Ti³⁺ ions; and
Pd²⁺ ions.

2. The solution, as recited in claim 1, further comprising amine ligands.

3. The solution, as recited in claim 2, wherein the reducing agent is Ti³⁺, further comprising at least one of citrate and gluconate or tartrate ions

4. The solution, as recited in claim 3, wherein the solution has a pH between 2 and 7, inclusive.

5. The solution, as recited in claim 4, further comprising Cl⁻ ions.

6. The solution, as recited in claim 5, wherein a ratio of Ti³⁺ to Pd²⁺ ion is between 100:1 to 2:1.

7. The method, as recited in claim 6, wherein the solution is boron, phosphorus, hydrazine, and formaldehyde free.

8. A method for providing an electroless plating of a palladium containing layer, comprising:
providing a Ti³⁺ or Co²⁺ concentrated stock solution;
providing a Pd²⁺ concentrated stock solution;
combining a flow from the Ti³⁺ or Co²⁺ concentrated stock solution with a flow from the Pd²⁺ concentrated stock solution and water to provide a mixed electrolyte for electrolessly depositing Pd; and
exposing a substrate to the mixed electrolyte for electrolessly depositing Pd.

9. The method, as recited in claim 8, wherein exposing the wafer to the mixed electrolyte for electrolessly depositing Pd, comprises:
providing a solution temperature between 10° to 40° C., inclusive; and
providing a pH of between 2 and 7, inclusive.

10. The method, as recited in claim 9, further comprising disposing the mixed electrolyte solution.

11. The method, as recited in claim 10, wherein the palladium containing layer is 99.9% pure palladium.

12. The method, as recited in claim 9, further comprising reactivating the mixed electrolyte solution.

13. The method, as recited in claim 8, wherein the Ti³⁺ or Co²⁺ concentrated stock solution comprises a solution of TiCl₃ or CoSO₄.

14. The method, as recited in claim 13, wherein the Pd²⁺ concentrated stock solution comprises a solution of PdCl₂ and ammonium hydroxide and sodium gluconate or gluconic acid.

15. The method, as recited in claim 14, wherein the Pd²⁺ concentrated stock solution has a shelf life of over a month.

16. The method, as recited in claim 15, wherein the Ti³⁺ or Co²⁺ concentrated stock solution has a shelf life of over a month.

17. The method, as recited in claim 14, wherein the mixed electrolyte solution is boron, phosphorus, hydrazine, and formaldehyde free.

18. The method, as recited in claim 8, wherein the mixed electrolyte solution is boron, phosphorus, hydrazine, and formaldehyde free.

19. A method for providing an electroless plating of a palladium layer, comprising:
providing a solution for electroless deposition of palladium, comprising:
Ti³⁺ or Co²⁺ ions; and
Pd²⁺ ions, wherein a ratio of Ti³⁺ or Co²⁺ ions to Pd²⁺ ion is between 100:1 to 2:1; and
exposing a substrate to the solution for electroless deposition of palladium.

20. The method, as recited in claim 19, wherein the providing the solution, provides the solution at a pH of between 2 and 7, inclusive, and at a temperature between 10° to 40° C., inclusive.
